(19) United States
(12) Patent Application Publication
(10) Pub. No.: US 2025/0098250 A1
(43) Pub. Date: Mar. 20, 2025

(54) SEMICONDUCTOR STRUCTURE AND MANUFACTURING METHOD THEREOF

(71) Applicant: Winbond Electronics Corp., Taichung City (TW)

(72) Inventors: Noriaki Ikeda, Kaohsiung City (TW); Chun-Sheng Yang, Taichung City (TW); Hao-Chuan Chang, Kaohsiung City (TW)

(73) Assignee: Winbond Electronics Corp., Taichung City (TW)

(21) Appl. No.: 18/780,512

(22) Filed: Jul. 23, 2024

(30) Foreign Application Priority Data
Sep. 18, 2023 (TW) 112135555

(51) Int. Cl. H01L 29/161; H01L 21/02; H01L 29/423

(52) U.S. Cl. CPC H10D 62/832; H01L 21/02532; H01L 21/0262; H10D 64/518

(57) ABSTRACT

A semiconductor structure including a substrate, a first electrode, a first dielectric layer, and a second electrode is provided. The first electrode is located on the substrate. The first electrode is pillar-shaped. The first dielectric layer is located on the first electrode. The second electrode is located on the first dielectric layer. The second electrode includes a first silicon germanium (SiGe) layer and a second SiGe layer. The first SiGe layer is located on the first dielectric layer. The second SiGe layer is located on the first SiGe layer. A content of germanium in the second SiGe layer is greater than a content of germanium in the first SiGe layer.

### CROSS-REFERENCE TO RELATED APPLICATION

This application claims the priority benefit of Taiwan application serial no. 112135555, filed on Sep. 18, 2023. The entirety of the above-mentioned patent application is hereby incorporated by reference herein and made a part of this specification.

### BACKGROUND

### Technical Field

The invention relates to a semiconductor structure and a manufacturing method thereof, and particularly relates to a semiconductor structure having a silicon germanium (SiGe) layer and a manufacturing method thereof.

### Description of Related Art

In some semiconductor structures (e.g., dynamic random access memory (DRAM) structures), the SiGe layer is used as the electrode. However, how to effectively improve the reliability of the semiconductor structure and reduce the processing time of the semiconductor structure are the goals of continuous efforts.

### SUMMARY

The invention provides a semiconductor structure and a manufacturing method thereof, which can effectively improve the reliability of the semiconductor structure and reduce the processing time of the semiconductor structure.

The invention provides a semiconductor structure, which includes a substrate, a first electrode, a first dielectric layer, and a second electrode. The first electrode is located on the substrate. The first electrode is pillar-shaped. The first dielectric layer is located on the first electrode. The second electrode is located on the first dielectric layer. The second electrode includes a first SiGe layer and a second SiGe layer. The first SiGe layer is located on the first dielectric layer. The second SiGe layer is located on the first SiGe layer. The content of germanium in the second SiGe layer is greater than the content of germanium in the first SiGe layer.

The invention provides a manufacturing method of a semiconductor structure, which includes the following steps. A substrate is provided. A first electrode is formed on the substrate. The first electrode is pillar-shaped. A first dielectric layer is formed on the first electrode. A second electrode is formed on the first dielectric layer. The second electrode includes a first SiGe layer and a second SiGe layer. The first SiGe layer is located on the first dielectric layer. The second SiGe layer is located on the first SiGe layer. The method of forming the first SiGe layer includes performing a furnace process. The method of forming the second SiGe layer includes performing a chemical vapor deposition process.

Based on the above description, in the semiconductor structure and the manufacturing method thereof according to the invention, the second electrode includes the first SiGe layer and the second SiGe layer, the second SiGe layer is located on the first SiGe layer, and the content of germanium in the second SiGe layer is greater than the content of germanium in the first SiGe layer. Therefore, the process of the first SiGe layer and the process of the second SiGe layer can be optimized, thereby effectively improving the reliability of the semiconductor structure and reducing the processing time of the semiconductor structure. In addition, since the second SiGe layer has a higher germanium content, the second SiGe layer can have a lower resistance.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are cross-sectional views of a manufacturing process of a semiconductor structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

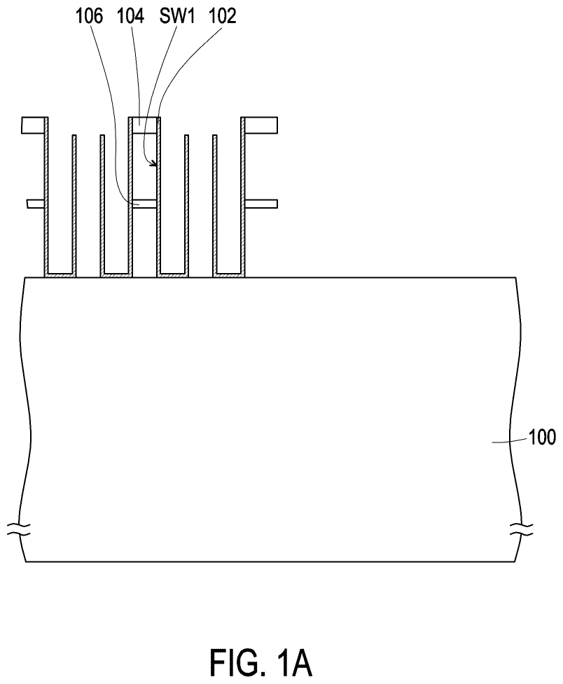

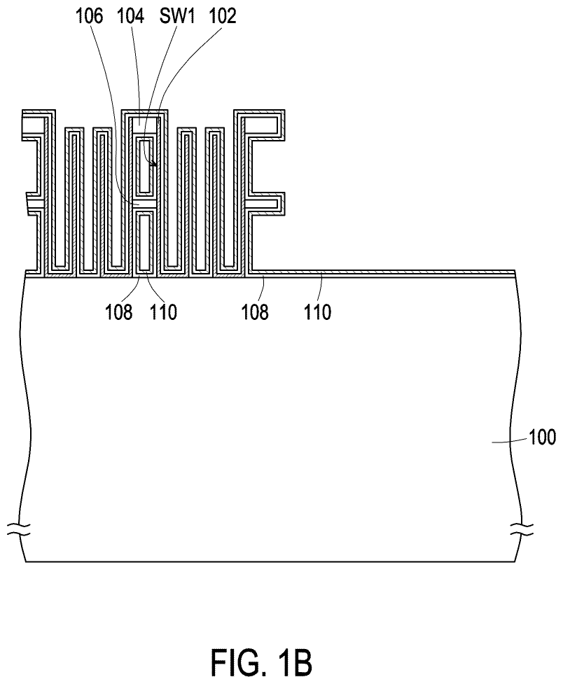

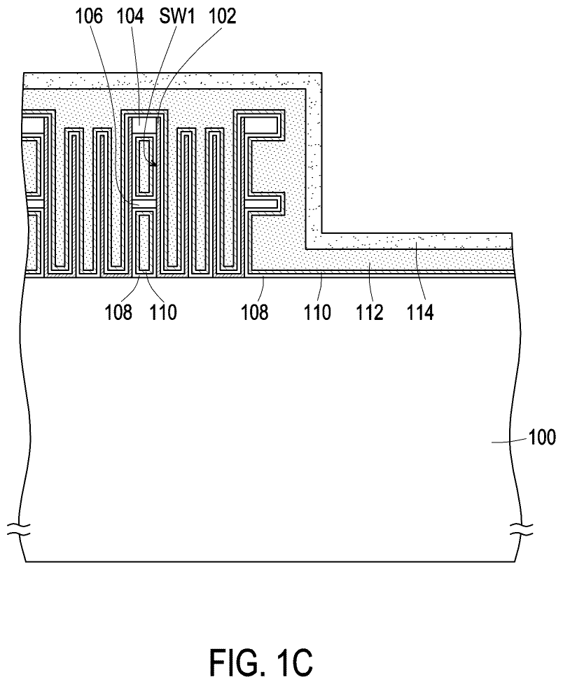

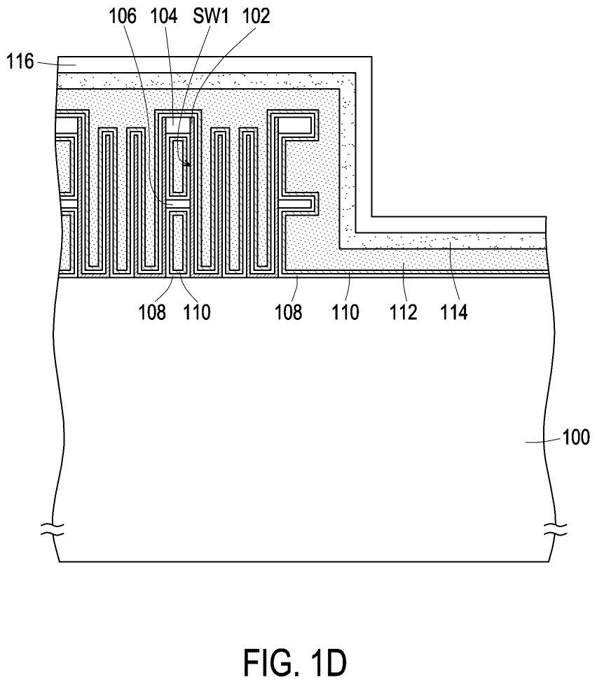

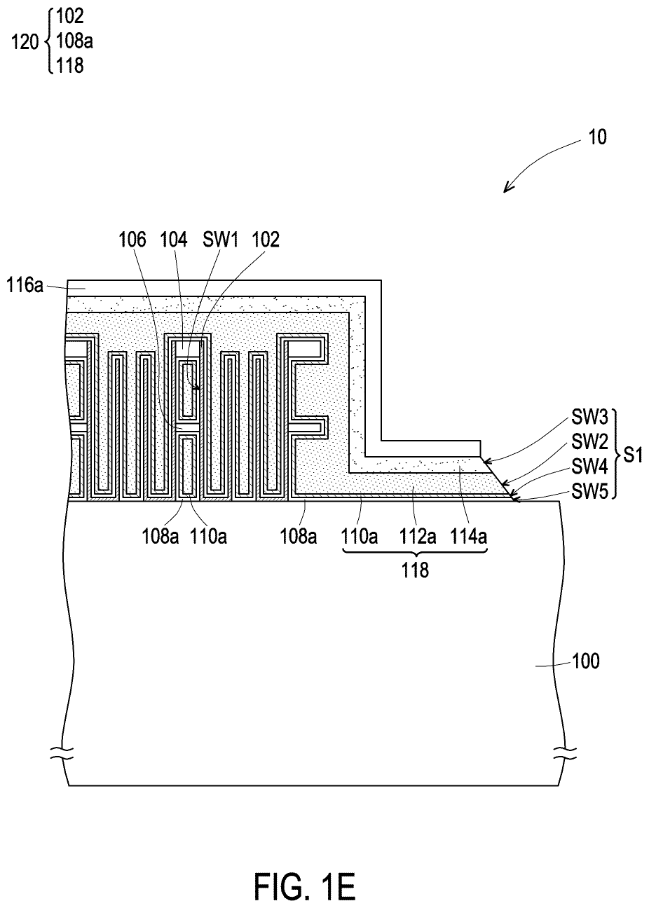

Referring to FIG. 1A, a substrate 100 is provided. The substrate 100 may be a semiconductor substrate such as a silicon substrate. In addition, although not shown in the FIGURE, the substrate 100 may have corresponding components thereon or therein depending on the type of the semiconductor structure. For example, the substrate 100 may have required components (not shown) therein, such as isolation structures, doped regions, and/or buried word lines, the substrate 100 may have required components (not shown) thereon, such as dielectric layers and/or interconnect structures (e.g., bit lines and contacts), and the description thereof is omitted here.

An electrode 102 is formed on the substrate 100. The electrode 102 is pillar-shaped. In some embodiments, the material of the electrode 102 is, for example, titanium nitride (TiN). In the present embodiment, the number of electrodes 102 is multiple, but the invention is not limited thereto. As long as the number of the electrodes 102 is at least one, it falls within the scope of the invention.

A support layer 104 is formed on the sidewall SW1 of the electrode 102. In some embodiments, the material of the support layer 104 is, for example, nitride (e.g., silicon nitride). A support layer 106 is formed on the sidewall SW1 of the electrode 102. The support layer 106 is located between the support layer 104 and the substrate 100. In some embodiments, the material of the support layer 106 is, for example, nitride (e.g., silicon nitride).

Referring to FIG. 1B, a dielectric material layer 108 is formed on the electrode 102. In some embodiments, the material of the dielectric material layer 108 is, for example, a high dielectric constant (high-k) dielectric material. In some embodiments, the method of forming the dielectric material layer 108 is, for example, a chemical vapor deposition method. A conductive material layer 110 is formed on the dielectric material layer 108. In some embodiments, the material of the conductive material layer 110 is, for example, titanium nitride. In some embodiments, the method of forming the conductive material layer 110 is, for example, a chemical vapor deposition method.

Referring to FIG. 1C, a SiGe material layer 112 is formed on the dielectric material layer 108. The SiGe material layer 112 may be formed by a furnace process. In some embodiments, the duration of the furnace process may be 1 hour to 5 hours, and the temperature of the furnace process may be 400° C. to 430° C. A SiGe material layer 114 may be formed on the SiGe material layer 112. The SiGe material layer 114 may be formed by a chemical vapor deposition process. In some embodiments, the duration of the chemical vapor deposition process may be 3 minutes to 5 minutes, and the temperature of the chemical vapor deposition process may be 400° C. to 430° C.

Referring to FIG. 1D, a dielectric material layer 116 may be formed on the SiGe material layer 114. In some embodiments, the material of the dielectric material layer 116 may be oxide (e.g., silicon oxide). In some embodiments, the material of the dielectric material layer 116 is, for example, tetraethoxysilane (TEOS) silicon oxide. In some embodiments, the method of forming the dielectric material layer 116 is, for example, a chemical vapor deposition method.

Referring to FIG. 1E, the dielectric material layer 116, the SiGe material layer 114, the SiGe material layer 112, the conductive material layer 110, and the dielectric material layer 108 may be patterned to form a dielectric layer 116a, a SiGe layer 114a, a SiGe layer 112a, a conductive layer 110a, and a dielectric layer 108a. Therefore, the dielectric layer 108a may be formed on the electrode 102, an electrode 118 may be formed on the dielectric layer 108a, and the dielectric layer 116a may be formed on the electrode 118. The electrode 118 includes a SiGe layer 112a and a SiGe layer 114a. The SiGe layer 112a is located on the dielectric layer 108a. The SiGe layer 114a is located on the SiGe layer 112a. The content of germanium in the SiGe layer 114a is greater than the content of germanium in the SiGe layer 112a. In some embodiments, the electrode 118 may further include the conductive layer 110a. The conductive layer 110a is located between the SiGe layer 112a and the dielectric layer 108a. In some embodiments, the dielectric material layer 116, the SiGe material layer 114, the SiGe material layer 112, the conductive material layer 110, and the dielectric material layer 108 may be patterned by a lithography process and an etching process. In some embodiments, the etching process is, for example, a dry etching process.

Hereinafter, a semiconductor structure 10 of the present embodiment will be described with reference to FIG. 1E. In addition, although the method for forming the semiconductor structure 10 is described by taking the above method as an example, the invention is not limited thereto.

Referring to FIG. 1E, the semiconductor structure 10 includes a substrate 100, an electrode 102, a dielectric layer 108a, and an electrode 118. In some embodiments, the semiconductor structure 10 may be a memory structure such as a dynamic random access memory (DRAM) structure. In addition, the electrode 102, the dielectric layer 108a, and the electrode 118 may form a capacitor 120. In some embodiments, the capacitor 120 may be used as a capacitor in a dynamic random access memory.

The electrode 102 is located on the substrate 100. The electrode 102 is pillar-shaped. In some embodiments, the cross-sectional shape of the electrode 102 may be a U-shape. The dielectric layer 108a is located on the electrode 102. The electrode 118 is located on the dielectric layer 108a. The electrode 118 includes a SiGe layer 112a and a SiGe layer 114a. The SiGe layer 112a is located on the dielectric layer 108a. The SiGe layer 114a is located on the SiGe layer 112a. The content of germanium in the SiGe layer 114a is greater than the content of germanium in the SiGe layer 112a. In some embodiments, the atomic percent of germanium in the SiGe layer 114a may be greater than the atomic percent of germanium in the SiGe layer 112a. In some embodiments, the content of germanium in the SiGe layer 112a may be 50 atomic % to 60 atomic %, and the content of germanium in the SiGe layer 114a may be 70 atomic % to 90 atomic %. In some embodiments, the hardness of the SiGe layer 112a may be greater than the hardness of the SiGe layer 114a. In some embodiments, the density of the SiGe layer 112a may be greater than the density of the SiGe layer 114a. In some embodiments, the SiGe layer 112a may include P-type dopants (e.g., boron). In some embodiments, the SiGe layer 114a may include P-type dopants (e.g., boron). The electrode 118 may further include a conductive layer 110a. The conductive layer 110a is located between the SiGe layer 112a and the dielectric layer 108a.

In some embodiments, there may be an inclined surface S1 at the end of the electrode 118. In some embodiments, the inclined surface S1 may include the sidewall SW2 of the SiGe layer 112a and the sidewall SW3 of the SiGe layer 114a. In some embodiments, the inclined surface S1 may further include the sidewall SW4 of the conductive layer 110a. In some embodiments, the inclined surface S1 may further include the sidewall SW5 of the dielectric layer 108a.

The semiconductor structure 10 may further include at least one of a support layer 104, a support layer 106, and a dielectric layer 116a. The support layer 104 is located on the sidewall SW1 of the electrode 102. The support layer 106 is located on the sidewall SW1 of the electrode 102. The support layer 106 may be located between the support layer 104 and the substrate 100. The dielectric layer 116a is located on the electrode 118.

Based on the above, in the semiconductor structure 10 and the manufacturing method thereof, the electrode 118 includes the SiGe layer 112a and the SiGe layer 114a, the SiGe layer 114a is located on the SiGe layer 112a, and the content of germanium in the SiGe layer 114a is greater than the content of germanium in the SiGe layer 112a. Therefore, the process of the SiGe layer 112a and the process of the SiGe layer 114a can be optimized, thereby effectively improving the reliability of the semiconductor structure 10 and reducing the processing time of the semiconductor structure 10. In addition, since the SiGe layer 114a has a higher germanium content, the SiGe layer 114a can have a lower resistance.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
a first electrode located on the substrate, wherein the first electrode is pillar-shaped;
a first dielectric layer located on the first electrode; and
a second electrode located on the first dielectric layer, wherein the second electrode comprises:
a first silicon germanium (SiGe) layer located on the first dielectric layer; and
a second SiGe layer located on the first SiGe layer, wherein a content of germanium in the second SiGe layer is greater than a content of germanium in the first SiGe layer, and an atomic percent of germanium in the second SiGe layer is greater than an atomic percent of germanium in the first SiGe layer.

2. The semiconductor structure according to claim 1, wherein a cross-sectional shape of the first electrode comprises a U-shape.

3. The semiconductor structure according to claim 1, wherein there is an inclined surface at an end of the second electrode.

4. The semiconductor structure according to claim 3, wherein the inclined surface comprises a sidewall of the first SiGe layer and a sidewall of the second SiGe layer.

5. The semiconductor structure according to claim 4, wherein the inclined surface further comprises a sidewall of the first dielectric layer.

6. The semiconductor structure according to claim 1, wherein the content of germanium in the first SiGe layer is 50 atomic % to 60 atomic %, and the content of germanium in the second SiGe layer is 70 atomic % to 90 atomic %.

7. The semiconductor structure according to claim 1, wherein a hardness of the first SiGe layer is greater than a hardness of the second SiGe layer.

8. The semiconductor structure according to claim 1, wherein a density of the first SiGe layer is greater than a density of the second SiGe layer.

9. The semiconductor structure according to claim 1, wherein the first SiGe layer comprises P-type dopants, and the second SiGe layer comprises P-type dopants.

10. The semiconductor structure according to claim 1, further comprising:
a first support layer located on a sidewall of the first electrode;
a second support layer located on the sidewall of the first electrode and located between the first support layer and the substrate; and
a second dielectric layer located on the second electrode, wherein
the second electrode further comprises:
a conductive layer located between the first SiGe layer and the first dielectric layer.

11. A manufacturing method of a semiconductor structure, comprising:
providing a substrate;
forming a first electrode on the substrate, wherein the first electrode is pillar-shaped;
forming a first dielectric layer on the first electrode; and
forming a second electrode on the first dielectric layer, wherein the second electrode comprises:
a first SiGe layer located on the first dielectric layer; and
a second SiGe layer located on the first SiGe layer, wherein a method of forming the first SiGe layer comprises performing a furnace process, and a method of forming the second SiGe layer comprises performing a chemical vapor deposition process.

12. The manufacturing method of the semiconductor structure according to claim 11, wherein there is an inclined surface at an end of the second electrode.

13. The manufacturing method of the semiconductor structure according to claim 11, wherein a method of forming the first dielectric layer, the first SiGe layer, and the second SiGe layer comprises:
forming a dielectric material layer on the first electrode;
forming a first SiGe material layer on the dielectric material layer;
forming a second SiGe material layer on the first SiGe material layer; and
patterning the second SiGe material layer, the first SiGe material layer, and the dielectric material layer to form the second SiGe layer, the first SiGe layer, and the first dielectric layer.

14. The manufacturing method of the semiconductor structure according to claim 11, wherein a content of germanium in the second SiGe layer is greater than a content of germanium in the first SiGe layer.

15. The manufacturing method of the semiconductor structure according to claim 11, wherein a duration of the furnace process is 1 hour to 5 hours, and a duration of the chemical vapor deposition process is 3 minutes to 5 minutes.

16. The manufacturing method of the semiconductor structure according to claim 11, wherein a temperature of the furnace process is 400° C. to 430° C., and a temperature of the chemical vapor deposition process is 400° C. to 430° C.

17. The manufacturing method of the semiconductor structure according to claim 13, wherein the second SiGe material layer, the first SiGe material layer, and the dielectric material layer are patterned by a lithography process and an etching process.

18. The manufacturing method of the semiconductor structure according to claim 17, wherein the etching process comprises a dry etching process.

19. The manufacturing method of the semiconductor structure according to claim 11, further comprising:
forming a first support layer on a sidewall of the first electrode;
forming a second support layer on the sidewall of the first electrode, wherein the second support layer is located between the first support layer and the substrate; and
forming a second dielectric layer on the second electrode.
